(19) United States
(12) Patent Application Publication
(10) Pub. No.: US 2025/0046694 A1
(43) Pub. Date: Feb. 6, 2025

(54) ELECTRONIC DEVICE AND MANUFACTURING METHOD OF ELECTRONIC DEVICE

(71) Applicant: Innolux Corporation, Miaoli County (TW)

(72) Inventors: Ying-Jen Chen, Miaoli County (TW); Wei-Lun Shieh, Miaoli County (TW)

(73) Assignee: Innolux Corporation, Miaoli County (TW)

(21) Appl. No.: 18/766,677

(22) Filed: Jul. 9, 2024

Related U.S. Application Data
(60) Provisional application No. 63/530,699, filed on Aug. 4, 2023.

(30) Foreign Application Priority Data
Apr. 23, 2024 (CN) 202410493250.7

(51) Int. Cl. H01L 23/498; H01L 21/48; H01L 23/15; H05K 1/03; H05K 1/11; H05K 3/40

(52) U.S. Cl. CPC H01L 23/49827; H01L 21/486; H01L 23/15; H01L 23/49833; H05K 1/0306; H05K 1/115; H05K 3/4038

(57) ABSTRACT

An electronic device including a glass substrate, a first circuit structure, and a second circuit structure. The glass substrate has a first side and a second side opposite to the first side, and includes a through via. The first circuit structure is disposed on the first side. The first circuit structure at least partially overlaps the through via. The second circuit structure is disposed on the second side. The second circuit structure at least partially overlaps the through via. The first circuit structure and the second circuit structure are electrically connected through the through via, and a thickness of the glass substrate is greater than or equal to 50 micrometers (μm) and less than or equal to 2 millimeters (mm).

### CROSS-REFERENCE TO RELATED APPLICATION

This application claims the priority benefits of U.S. provisional application Ser. No. 63/530,699, filed on Aug. 4, 2023 and China application serial no. 202410493250.7, filed on Apr. 23, 2024. The entirety of each of the above-mentioned patent applications is hereby incorporated by reference herein and made a part of this specification.

### BACKGROUND

### Technical Field

The disclosure relates to an electronic device and a manufacturing method of the electronic device.

### Description of Related Art

After forming a through glass via in the glass substrate (TGV), the glass substrate is difficult to be adsorbed on the vacuum adsorption table due to the presence of glass through vias, causing the glass substrate to easily move during the manufacturing process and reducing the yield of electronic devices. In addition, when the layers on the glass substrate are subjected to a yellowing process, the photoresist formed by the coating process will flow into the glass through vias and contaminate the machine below the glass substrate, which increases the time and the cost required to clean the contaminated machine.

### SUMMARY

Some embodiments of the disclosure are directed to an electronic device that has relatively proper yield and/or relatively low process cost.

An electronic device provided according to some embodiments of the disclosure includes a glass substrate, a first circuit structure, and a second circuit structure. The glass substrate has a first side and a second side relative to the first side and includes a through via. The first circuit structure is disposed on the first side. The first circuit structure at least partially overlaps the through via. The second circuit structure is disposed on the second side. The second circuit structure at least partially overlaps the through via. The first circuit structure and the second circuit structure are electrically connected through the through vias. A thickness of the glass substrate is greater than or equal to 50 μm and less than or equal to 2 mm.

Some embodiments of the disclosure are directed to a manufacturing method of an electronic device, which manufactures an electronic device with a relatively proper yield and/or a relatively low process cost.

A method of manufacturing an electronic device provided according to some embodiments of the disclosure includes the following steps. First, a glass substrate is provided. The glass substrate has a first side and a second side relative to the first side. Next, a first opening is formed on the first side. Next, a second opening is formed on the second side. Afterwards, the first circuit structure is formed on the first side. The first circuit structure at least partially overlaps the first opening. Then, the second circuit structure is formed on the second side. The second circuit structure at least partially overlaps the second opening. The first opening and the second opening are connected to form the through via of the glass substrate, and the first circuit structure and the second circuit structure are electrically connected through the through via.

To make the aforementioned more comprehensible, several embodiments accompanied with drawings are described in detail as follows.

### BRIEF DESCRIPTION OF THE DRAWINGS

FIG. 1 is a schematic flowchart of a manufacturing method of an electronic device according to the first embodiment of the disclosure.

FIG. 2 is a schematic flowchart of a manufacturing method of an electronic device according to the second embodiment of the disclosure.

FIG. 3 is a schematic flowchart of a manufacturing method of an electronic device according to the third embodiment of the disclosure.

FIG. 4 is a partial cross-sectional view of the electronic device according to the first embodiment of the disclosure.

FIG. 5 is a partial cross-sectional view of an electronic device according to the second embodiment of the disclosure.

FIG. 6 is a partial cross-sectional view of an electronic device according to the third embodiment of the disclosure.

### DESCRIPTION OF THE EMBODIMENTS

Reference will now be made in detail to the exemplary embodiments. Examples of exemplary embodiments are described in the accompanying drawings. Wherever possible, the same reference symbols are used to denote the same or similar parts in the drawings and the description.

The disclosure may be understood by referring to the following detailed description with reference to the accompanying drawings. It is noted that for comprehension of the reader and simplicity of the drawings, in the drawings provided in the disclosure, only a part of the communication device is shown, and certain devices in the drawings are not necessarily drawn to actual scale. Moreover, the quantity and the size of each device in the drawings are only schematic and exemplary and are not intended to limit the scope of protection provided in the disclosure.

Throughout the specification and appended claims of the disclosure, certain terms are used to refer to specific components. People skilled in the art should understand that manufacturers of communication devices may refer to same elements under different names. The disclosure does not intend to distinguish devices with the same functions but different names. In the following specification and claims, the words “including”, “containing”, and “having” are open-ended words and therefore should be interpreted as “containing but not limited to . . . ”. Therefore, when the terms “including,” “containing,” and/or “having” are used in the description of the disclosure, the terminologies designate the presence of a corresponding feature, region, step, operation, and/or element, but do not exclude the presence of one or more corresponding features, regions, steps, operations, and/or elements.

Directional terminologies mentioned herein, such as “top”, “bottom”, “front”, “back”, “left”, “right”, and so forth, refer to directions in the accompanying reference drawings. Accordingly, the directional terminologies provided herein serve to describe rather than limiting the disclosure. In the accompanying drawings, each figure illustrates methods applied in particular embodiments and general features of structures and/or materials in the embodiments. However, these figures should not be construed or defined as the scope covered by the particular embodiments. For instance, relative dimensions, thicknesses, and positions of various layers, regions, and/or structures may be reduced or enlarged for clarity.

When a corresponding element (such as a film layer or a region) is referred to as being “on another element”, the element may be directly on the other element or there may be another element between the two. On the other hand, when an element is referred to as being “directly on another element”, there is no element between the two. Also, when an element is referred to as being “on another element”, the two have a top-down relationship in the top view direction, and the element may be above or below the other element, and the top-down relationship depends on the orientation of the device.

The terminologies “about”, “equal to”, “equivalent to” or “same”, “substantially” or “approximately” are generally interpreted as being within 10% of a given value or range, or interpreted as being within 5%, 3%, 2%, 1%, or 0.5% of a given value or range.

The ordinal numbers used in the specification and claims, such as “first”, “second”, etc., are used to modify the elements, and they do not imply or represent the (or these) elements have any previous ordinal numbers, do not represent the order of an element and another element, or the order of a manufacturing method. The use of these ordinal numbers is only used to clearly distinguish an element with a certain name from another element with the same name. The terms used in the claims and the specification may not have to be the same, and accordingly, the first component provided in the specification may be the second component in the claims.

It should be understood that the following embodiments may replace, reorganize, and mix the features in several different embodiments to complete other embodiments without departing from the spirit of the disclosure. As long as the features of the embodiments do not violate the spirit of the disclosure or conflict each other, they may be mixed and matched as desired.

An electrical connection or coupling relationship described in this disclosure may refer to a direct connection or an indirect connection. In the case of the direct connection, end points of the elements on two circuits are directly connected or connected to each other by a conductor segment, and in the case of the indirect connection, there are switches, diodes, capacitors, inductors, resistors, other appropriate elements, or a combination of the above elements between the end points of the elements on the two circuits, which should not be construed as a limitation in the disclosure.

In this disclosure, measurement of thickness, length, and width may be done by applying an optical microscope, and the thickness or the width may be obtained by measuring a cross-sectional image in an electron microscope, which should not be construed as a limitation in the disclosure. In addition, certain errors between any two values or directions for comparison may be acceptable. If a first value is equal to a second value, it implies that there may be an error of about 10% between the first value and the second value. If a first direction is perpendicular to a second direction, an angle difference between the first direction and the second direction may be between 80 degrees and 100 degrees; if the first direction is parallel to the second direction, an angle difference between the first direction and the second direction may be between 0 degrees and 10 degrees.

In this disclosure, electronic devices may include power modules, semiconductor devices, packaging devices, display devices, backlight modules, solar cells, sensing devices, automotive devices, high-frequency devices, antenna devices, lighting devices, splicing devices, package device or a combination of the above, but the disclosure is not limited thereto. The electronic device of the disclosure may include electronic components. The electronic components may include passive components, active components, or a combination of the above, such as integrated circuits (ICs), transistors, controlled silicon rectifiers, valves, thin film transistors, capacitors, resistors, inductors, variable capacitors, filters, resistors, diodes, microelectromechanical system components (MEMS), chips, etc., but are not limited thereto. The diodes include P-N Junction diodes, PIN diodes, constant current diodes, light emitting diodes, non light emitting diodes, and varactor diodes. The light emitting diodes may include, for example, organic light emitting diodes (OLEDs), mini LEDs, micro LEDs, quantum dot LEDs, fluorescence, phosphor or other suitable materials, or a combination of the above, but is not limited thereto. The chip may be made of silicon (Si), gallium arsenide (GaAs), gallium nitride (GaN), silicon carbide (SiC), sapphire, or a glass substrate, but is not limited thereto. The electronic device may include a system on a chip (SoC), a system in package (SiP), an antenna in package (AiP) or a combination of the above, but this disclosure is not limited thereto.

The manufacturing method of electronic devices may be through wafer level packaging (WLP), a panel level packaging (PLP), a ball grid array (BGA), a chip scale package (CSP), a chip on wafer on substrate (CoWoS), and other packaging methods, which may include, for example, chip-first or RDL first packaging methods, but the disclosure is not limited thereto.

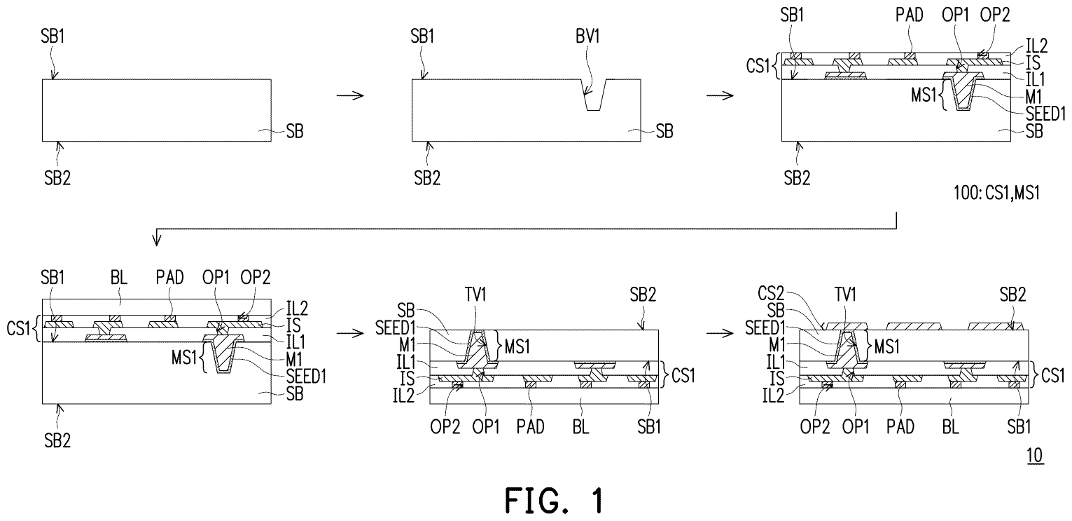

FIG. 1 is a schematic flowchart of a manufacturing method of an electronic device according to the first embodiment of the disclosure.

Referring to FIG. 1, in this embodiment, an electronic device 10 may be formed by performing the following steps, but the disclosure is not limited thereto.

In step (1), a glass substrate SB is provided. The glass substrate SB has, for example, a first side SB1 and a second side SB2 relative to the first side SB1. In some embodiments, the material of the glass substrate SB may include a suitable glass material. For example, the material of the glass substrate SB includes quartz glass, but the disclosure is not limited thereto.

In step (2), a first opening BV1 is formed on the first side SB1 of the glass substrate SB. In some embodiments, the first opening BV1 may be formed by performing a drilling process, an etching process, or a combination thereof. For example, a laser drilling process may be performed on the first side SB1 of the glass substrate S1 to form the first opening BV1, but the disclosure is not limited thereto. In this embodiment, the first opening BV1 is a blind via.

In step (3), a first connection structure 100 is formed on the first side SB1 of the glass substrate SB. In this embodiment, the first connection structure 100 includes a first metal structure MS1 disposed in the first opening BV1 of the glass substrate SB and a first circuit structure CS1 disposed on the glass substrate SB. The first connection structure 100 may be formed, for example, by performing the following steps, but the disclosure is not limited thereto.

In step (3-a), the first metal structure MS1 is formed on the first side SB1 of the glass substrate SB. The first metal structure MS1 is filled in the first opening BV1 of the glass substrate SB. In this embodiment, the first metal structure MS1 may be formed by performing the process described below, but the disclosure is not limited thereto.

First, a seed layer SEED1 is formed on the first side SB1 of the glass substrate SB. In some embodiments, the seed layer SEED1 may be formed by performing a physical vapor deposition process or a chemical vapor deposition process, but the disclosure is not limited thereto. The material of the seed layer SEED1 may be, for example, a metal, and may, for example, have a single-layer structure of a single metal or a composite layer structure having multiple sub-layers formed of different metals. The sub-layers are stacked on each other. For example, the seed layer SEED1 may include a titanium layer (not shown) and a copper layer (not shown) stacked on the titanium layer to have the composite layer structure, but the disclosure is not limited thereto.

Next, a mask layer (not shown) is formed on the first side SB1 of the glass substrate SB. The mask layer includes multiple openings exposing a portion of the seed layer SEED1.

Next, a metal layer M1 is formed in the openings of the mask layer. In some embodiments, the metal layer M1 may be formed by performing an electroplating process. That is, the metal layer M1 may be formed by performing the electroplating process to grow the seed layer SEED1. Based on this, the material of the metal layer M1 may be the same as the material of the seed layer SEED1, but the disclosure is not limited thereto.

At this point, the method of forming the metal structure MS1 is completed. The metal structure MS1 is the seed layer SEED1 and the metal layer M1 formed in the first opening BV1 of the glass substrate SB. In addition, the seed layer SEED1 and the metal layer M1 that are not formed in the first opening BV1 of the glass substrate SB are part of the first circuit structure CS1 that is described below.

In step (3-b), an insulation layer IL1 is formed on the first side SB1 of the glass substrate SB. In this embodiment, the insulation layer IL1 may be formed by performing the process described below.

First, an insulation material layer (not shown) covering the metal layer M1 is formed. The insulation material layer may be formed, for example, by using the chemical vapor deposition process, a coating process, or other suitable processes, but the disclosure is not limited thereto.

Next, a patterning process is performed on the insulation material layer to form the insulation layer IL1 having multiple openings OP1. The openings OP1 expose part of the metal layer M1.

In some embodiments, the material of the insulation layer IL1 may include inorganic materials (such as silicon oxide, silicon nitride, or silicon oxynitride), but the disclosure is not limited thereto. In some embodiments, the insulation layer IL1 may have the single-layer structure or a multi-layer structure, but the disclosure is not limited thereto.

In step (3-c), an interconnect structure IS is formed on the first metal structure MS1. The interconnect structure IS is electrically connected to the metal structure MS1. In some embodiments, the forming method of the interconnect structure IS may be the same or similar to the forming method of the first metal structure MS1 described in the step (3-a), that is, the interconnect structure IS may also include a seed layer (not shown) and a metal layer (not shown) stacked thereon, but the disclosure is not limited thereto. Based on this, the structures and materials included in the interconnect structure IS may refer to the above embodiments, which are not be repeated herein.

In step (3-d), an insulation layer IL2 is formed on the interconnect structure IS. In this embodiment, the insulation layer IL2 may be formed by performing the process described below.

First, an insulation material layer (not shown) covering the interconnect structure IS is formed. The insulation material layer may be formed, for example, by using the chemical vapor deposition process, a coating process, or other suitable processes, but the disclosure is not limited thereto.

Next, the patterning process is performed on the insulation material layer to form an insulation layer IL2 having multiple openings OP2. The openings OP2 expose part of the interconnect structure IS.

In some embodiments, the material of the insulation layer IL2 may include organic materials (such as polyimide resin, epoxy resin, or acrylic resin) or inorganic materials (such as silicon oxide, silicon nitride, or silicon oxynitride). In this embodiment, the insulation layer IL2 is a solder resist layer, and includes the material of epoxy resin, but the disclosure is not limited thereto. In some embodiments, the insulation layer IL2 may have the single-layer structure or the multi-layer structure, but the disclosure is not limited thereto.

In step (3-e), a pad PAD is formed in the openings OP2 of the insulation layer IL2. In some embodiments, the pad PAD may be formed by performing an electroless nickel immersion gold (ENIG) process. Based on this, the material of the pad PAD may include an alloy of gold and nickel, but the disclosure is not limited thereto.

At this point, the method for forming the first circuit structure CS1 of this embodiment is completed. The first circuit structure CS1 is the seed layer SEED1, the metal layer M1, the insulation layer IL1, the interconnect structure IS, the insulation layer IL2, and the pad PAD which are disposed on the glass substrate SB and are not disposed in the first opening BV1, but the disclosure is not limited thereto. In this embodiment, the first circuit structure CS1 is formed on the first side SB1 and at least partially overlaps the first opening BV1.

In addition, the method of forming the first connection structure 100 of this embodiment has also been completed, but the method of forming the first connection structure 100 provided by the disclosure is not limited thereto.

In step (4), after forming the first circuit structure CS1, a protective layer BL may be formed on a surface of the first circuit structure CS1 away from the glass substrate SB, in which the protective layer BL covers the pad PAD. In some embodiments, the protective layer BL may be formed by performing an attachment process, but the disclosure is not limited thereto. The material of the protective layer BL may be, for example, a suitable organic material, but the disclosure is not limited thereto.

In step (5A), a thinning process is performed on the second side SB2 of the glass substrate SB to expose part of the first metal structure MS1 of the first connection structure 100 located in the first opening BV1. The glass substrate SB after the thinning process may, for example, have a thickness greater than or equal to 50 μm and less than or equal to 2 mm. Based on this, the first opening BV1 may be changed from the blind hole to a through via TV1 in the step (5A). In some embodiments, the thinning process performed on the second side SB2 of the glass substrate SB may include an etching process, a polishing process, a grinding process, or a combination thereof. For example, a wet etching process may be performed on the second side SB2 of the glass substrate SB, in which etching liquid used includes hydrofluoric acid, but the disclosure is not limited thereto.

In step (6A), a second circuit structure CS2 is formed on the second side SB2 of the glass substrate SB. The second circuit structure CS2 may be electrically connected to the first circuit structure CS1 through the first metal structure MS1 exposed by the second side SB2 of the glass substrate SB. In some embodiments, the second circuit structure CS2 may be formed by performing the physical vapor deposition process or the metal chemical vapor deposition process and then performing the patterning process, but the disclosure is not limited thereto. The second circuit structure CS2 may, for example, include multiple traces (not shown), multiple bondpads (not shown), or a combination thereof, but the disclosure is not limited thereto.

At this point, the manufacturing method of the electronic device 10 of this embodiment is completed, but the manufacturing method of the electronic device 10 provided by the disclosure is not limited thereto.

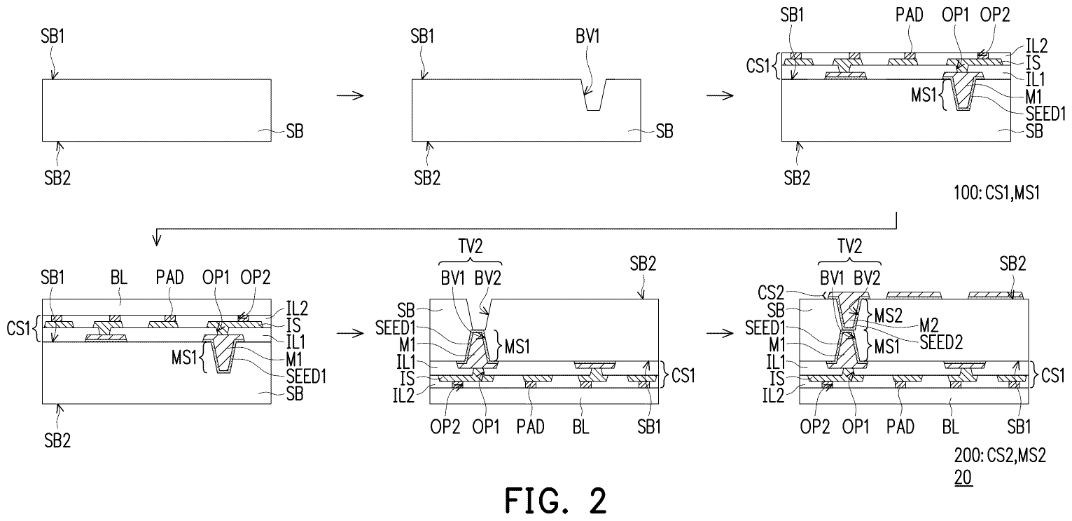

FIG. 2 is a schematic flowchart of a manufacturing method of an electronic device according to the second embodiment of the disclosure. It should be noted that the embodiment of FIG. 2 may use the same reference numerals and parts as the embodiment of FIG. 1, where the same reference numerals indicate the same or similar components, and the description of the same technical content is omitted.

Referring to FIG. 2, in this embodiment, an electronic device 20 may be formed by performing the following steps, but the disclosure is not limited thereto.

In the steps (1) to (4), the first connection structure 100 and the protective layer BL are sequentially formed on the glass substrate SB. In some embodiments, a thickness of the glass substrate SB may be greater than or equal to 50 μm and less than or equal to 2 mm. For example, the thickness of the glass substrate SB may be 50 μm, 70 μm, 100 μm, 500 μm, 1 mm, 1.5 mm, 2 mm or any of the above numerical ranges, but the disclosure is not limited thereto.

In step (5B), a second opening BV2 is formed on the second side SB2 of the glass substrate SB. The second opening BV2 exposes part of the first metal structure MS1 of the first connection structure 100 located in the first opening BV1. In some embodiments, the second opening BV2 may be formed by performing the drilling process, the etching process, or a combination thereof. For example, the glass substrate SB may be turned over first, and then a laser drilling process may be performed on the second side SB2 of the glass substrate SB to form the second opening BV2, but the disclosure is not limited thereto.

In this embodiment, the first opening BV1 and the second opening BV2 are connected to form a through via TV2 of the glass substrate SB. The first opening BV1 extends, for example, from the first side SB1 of the glass substrate SB to the inside of the glass substrate SB, and has an inverted trapezoid shape. The second opening BV2 extends, for example, from the second side SB2 of the glass substrate SB to the inside of the glass substrate SB, and has a normal trapezoid shape. Since the first opening BV1 and the second opening BV2 are formed in different steps, the junction of a side wall of the first opening BV1 and a side wall of the second opening BV2 may be discontinuous, and the first opening BV1 and the second opening BV2 are staggered to each other but are not limited thereto. In other embodiments, the junction of the side wall of the first opening BV1 and the side wall of the second opening BV2 may be continuous, so that the through via TV2 has a smooth side wall.

In step (6B), a second connection structure 200 is formed on the second side SB2 of the glass substrate SB. In this embodiment, the second connection structure 200 includes a second metal structure MS2 disposed in the second opening BV2 of the glass substrate SB and the second circuit structure CS2 disposed on the glass substrate SB. The second connection structure 200 may be formed, for example, by performing the following steps, but the disclosure is not limited thereto.

First, a seed layer SEED2 is formed on the second side SB2 of the glass substrate SB. The forming method of the seed layer SEED2 may be, for example, the same as or similar to the forming method of the seed layer SEED1, and therefore is not repeated herein.

Next, the mask layer (not shown) is formed on the second side SB2 of the glass substrate SB. The mask layer includes multiple openings that expose portions of the seed layer SEED2.

Then, a metal layer M2 is formed in the openings of the mask layer. The forming method of the metal layer M2 may be, for example, the same as or similar to the forming method of the metal layer M1, and therefore is not repeated herein.

At this point, the method of forming the second metal structure MS2 is completed. The second metal structure MS2 is the seed layer SEED2 and the metal layer M2 formed in the second opening BV2 of the glass substrate SB. In addition, the seed layer SEED2 and the metal layer M2 that are not formed in the second opening BV2 of the glass substrate SB serve as the second circuit structure CS2.

In this embodiment, the first circuit structure CS1 and the second circuit structure CS2 are electrically connected through the through via TV2 of the glass substrate SB. In detail, the first circuit structure CS1 and the second circuit structure CS2 may be electrically connected through the first metal structure MS1 and the second metal structure MS2 disposed in the through via TV2 of the glass substrate SB.

At this point, the manufacturing method of the electronic device 20 of this embodiment is completed, but the manufacturing method of the electronic device 20 provided by the disclosure is not limited thereto.

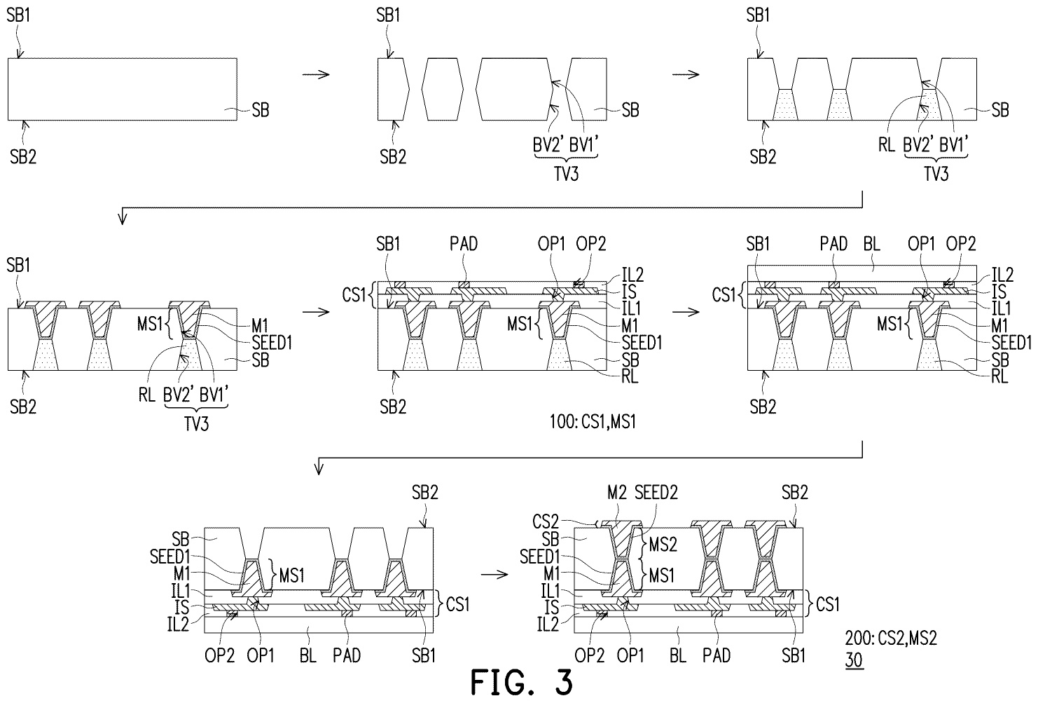

FIG. 3 is a schematic flowchart of a manufacturing method of an electronic device according to the third embodiment of the disclosure. It should be noted that the embodiment of FIG. 3 may use the same reference numerals and parts as the embodiment of FIG. 1, where the same reference numerals indicate the same or similar components, and the description of the same technical content is omitted.

Referring to FIG. 3, in this embodiment, an electronic device 30 may be formed by performing the following steps, but the disclosure is not limited thereto.

In step (11), the glass substrate SB is provided. The step (11) is, for example, the same as or similar to the step (1), and therefore is not repeated herein. In some embodiments, the thickness of the glass substrate SB may be greater than or equal to 50 μm and less than or equal to 2 mm. For example, the thickness of the glass substrate SB may be 50 μm, 70 μm, 100 μm, 500 μm, 1 mm, 1.5 mm, 2 mm or any of the above numerical ranges, but the disclosure is not limited thereto.

In step (12), a through via TV3 is formed in the glass substrate SB. In some embodiments, the through via TV3 may be formed by performing a combination of the drilling process and the etching process. For example, the laser drilling process may be performed on the first side SB1 and the second side SB2 of the glass substrate SB, and then the wet etching process may be performed together to form the through via TV3. The etching liquid used includes hydrofluoric acid, but the disclosure is limited thereto. In this embodiment, through the combination of the drilling process and the etching process, the through via TV3 penetrates the glass substrate SB and may have a dumbbell or hourglass shape. In detail, the through via TV3 may include a first opening BV1′ and a second opening BV2′. The first opening BV1′ extends to the inside of the glass substrate SB from the first side SB1 of the glass substrate SB, and has the inverted trapezoid shape. The second opening BV2′ extends to the inside of the glass substrate SB from the second side SB2 of the glass substrate SB, and has the normal trapezoidal shape. Since the through via TV3 of this embodiment is formed in the same step, the through via TV3 may have smooth side walls. That is, the junction between the side wall of the first opening BV1′ and the side wall of the second opening BV2′ may be continuous.

In step (13), a hole plugging material RL is formed in the second opening BV2′ of the glass substrate SB. In this embodiment, the hole plugging material RL may be formed by performing the process described below.

First, the hole plugging material RL is filled into the through via TV3. The hole plugging material RL may be filled into at least one of the first opening BV1′ and the second opening BV2′. For example, the hole plugging material RL may be filled into the first opening BV1′ and the second opening BV2′ at the same time. The hole plugging material RL may be formed, for example, by using the chemical vapor deposition process, the coating process, or other suitable processes, but the disclosure is not limited thereto.

Next, the etching process is performed to remove the hole plugging material RL located in the first opening BV1′ of the glass substrate SB. In some embodiments, the hole plugging material RL only fills the second opening BV2′, so the step of removing the first opening BV1′ may be omitted.

In step (14), the first connection structure 100 is formed on the first side SB1 of the glass substrate SB. In this embodiment, the first connection structure 100 includes the first metal structure MS1 disposed in the first opening BV1′ of the glass substrate SB and the first circuit structure CS1 disposed on the glass substrate SB. The step (14) is, for example, the same as or similar to the step (3), and therefore is not repeated herein.

In step (15), after forming the first circuit structure CS1, the protective layer BL may be formed on the surface of the first circuit structure CS1 away from the glass substrate SB. The protective layer BL covers the pad PAD. The step (15) is, for example, the same as or similar to the step (4), and therefore is not repeated herein.

In step (16), the etching process is performed to remove the hole plugging material RL located in the second opening BV2′ of the glass substrate SB.

In step (17), the second connection structure 200 is formed on the second side SB2 of the glass substrate SB. In this embodiment, the second connection structure 200 includes the second metal structure MS2 disposed in the second opening BV2′ of the glass substrate SB and the second circuit structure CS2 disposed on the glass substrate SB. The step (17) is, for example, the same as or similar to the step (6B), and therefore is not repeated herein.

At this point, the manufacturing method of the electronic device 30 of this embodiment is completed, but the manufacturing method of the electronic device 30 provided by the disclosure is not limited thereto.

In the disclosure, the manufacturing method of all electronic devices may further include forming a chip (not shown) on at least one of the first circuit structure CS1 and the second circuit structure CS2, so that the chip is electrically connected to at least one of the first circuit structure CS1 and the second circuit structure CS2. For example, the chip may be formed on the pad PAD and be electrically connected to the first circuit structure CS1 and the second circuit structure CS2, but it is not limited thereto. The manufacturing method of the disclosure may be a packaging method of an electronic device, and may be a redistribution layer structure first process.

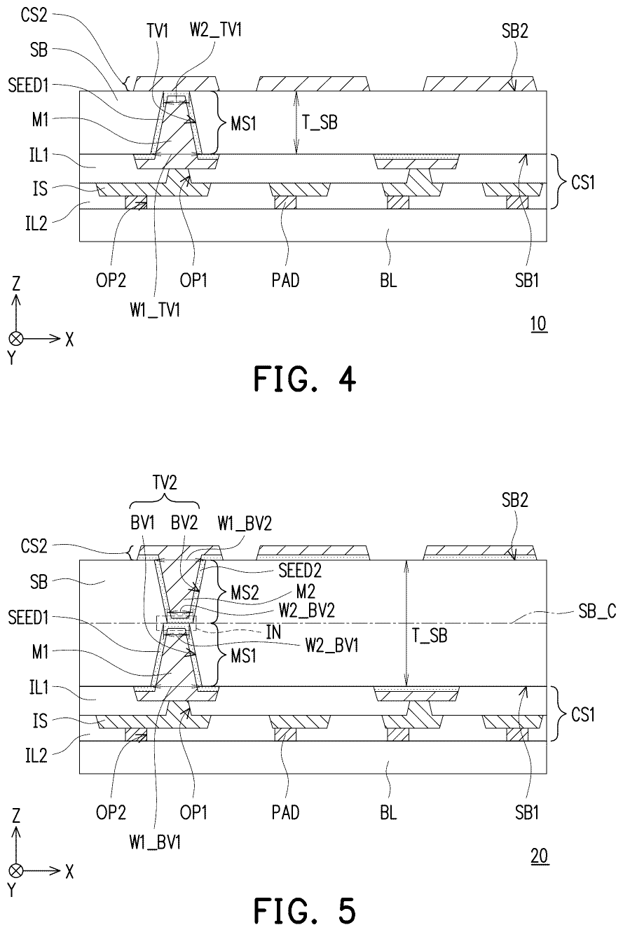

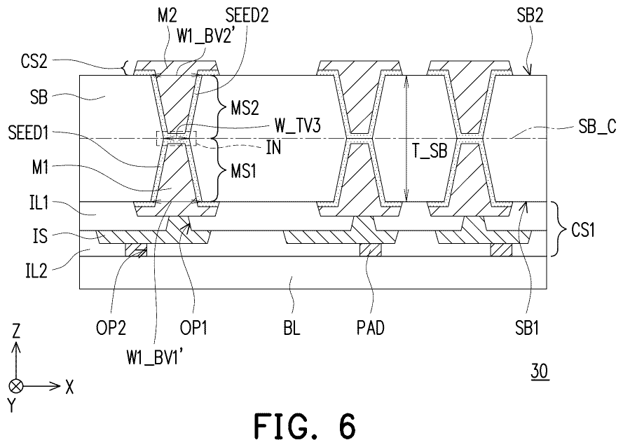

The structure of the electronic device 10, the electronic device 20, and the electronic device 30 of this embodiment are briefly introduced below with reference to FIG. 4, FIG. 5, and FIG. 6 respectively, but the disclosure is not limited thereto.

FIG. 4 is a partial cross-sectional view of the electronic device according to the first embodiment of the disclosure. It should be noted that the embodiment of FIG. 4 may use the same reference numerals and parts as the embodiment of FIG. 1, where the same reference numerals indicate the same or similar components, and the description of the same technical content is omitted.

In this embodiment, the electronic device 10 includes the glass substrate SB, the first circuit structure CS1, and the second circuit structure CS2.

The glass substrate SB has, for example, the first side SB1 and the second side SB2 relative to the first side SB1, and includes the through via TV1. The first side SB1 and the second side SB2 of the glass substrate SB are opposite to each other in a top view direction (a direction Z) of the electronic device 10, for example. In a cross-sectional direction (a direction Y) of the electronic device 10, the through via TV1 has a width W1_TV1 on the first side SB1 in a direction parallel to the glass substrate SB (a direction X), for example. The through via TV1 has a width W2_TV1 on the second side SB2 in the direction parallel to the glass substrate SB (the direction X), for example. In this embodiment, the width W1_TV1 of the through via TV1 on the first side SB1 is greater than the width W2_TV1 of the through via TV1 on the second side SB2. Therefore, the through via TV1 may have the inverted trapezoid shape, for example. In this embodiment, the glass substrate SB has a thickness T_SB greater than or equal to 50 μm and less than or equal to 2 mm in the top view direction (the direction Z) of the electronic device 10. For example, the thickness T_SB of the glass substrate SB may be 50 μm, 70 μm, 100 μm, 500 μm, 1 mm, 1.5 mm, 2 mm or any of the above numerical ranges, but the disclosure is not limited thereto.

The first circuit structure CS1 is, for example, disposed on the first side SB1 of the glass substrate SB. In this embodiment, the first circuit structure CS1 is part of the first connection structure 100. In detail, from another perspective, the first connection structure 100 includes the first metal structure MS1 disposed in the through via TV1 of the glass substrate SB and the first circuit structure CS1 disposed on the glass substrate SB (not disposed in the through via TV1). In this embodiment, the first circuit structure CS1 at least partially overlaps the through via TV1. For example, the interconnect structure IS is located on the first metal structure MS1 and overlaps the through via TV1. Based on this, the first circuit structure CS1 may be electrically connected to the first metal structure MS1 located in the through via TV1, for example. The first circuit structure CS1 and the first metal structure MS1 may each include the seed layer SEED1 and the metal layer M1. For detailed description, please refer to the above embodiments, which is not repeated herein.

The second circuit structure CS2 is, for example, disposed on the second side SB2 of the glass substrate SB. In this embodiment, the second circuit structure CS2 at least partially overlaps the through via TV1. Based on this, the second circuit structure CS2 may be electrically connected to the first circuit structure CS1 through the first metal structure MS1 exposed by the through via TV1 of the glass substrate SB. The second circuit structure CS2 may, for example, include the multiple traces (not shown), the multiple bondpads (not shown), or a combination thereof, but the disclosure is not limited thereto. In this embodiment, the seed layer SEED1 in the first metal structure MS1 is in contact with the second circuit structure CS2.

The first circuit structure CS1 and the second circuit structure CS2 may each be the single-layer structure or the multi-layer structure, for example. In some embodiments, the first circuit structure CS1 and the second circuit structure CS2 may each include a composite structure combining a conductive layer and an insulation layer. For example, the first circuit structure CS1 and the second circuit structure CS2 may be, for example, redistribution layer structures, but the disclosure is not limited thereto. The arrangement of the first circuit structure CS1 and the second circuit structure CS2 may be used to adjust a fan-out condition of the circuit and/or improve a fan-out area of the circuit, or to enable different electronic components (not shown) in the electronic device 10 to be electrically connected with each other.

FIG. 5 is a partial cross-sectional view of an electronic device according to the second embodiment of the disclosure. It should be noted that the embodiment of FIG. 5 may use the same reference numerals and parts as the embodiment of FIG. 2, where the same reference numerals indicate the same or similar components, and the description of the same technical content is omitted.

In this embodiment, the electronic device 20 includes the glass substrate SB, the first circuit structure CS1, and the second circuit structure CS2.

The glass substrate SB has, for example, the first side SB1 and the second side SB2 relative to the first side SB1 and includes the through via TV2. The first side SB1 and the second side SB2 of the glass substrate SB are opposite to each other in the top view direction (the direction Z) of the electronic device 20, for example. In this embodiment, the through via TV2 of the glass substrate SB is connected by the first opening BV1 formed on the first side SB1 and the second opening BV2 formed on the second side SB2. In the cross-sectional direction (the direction Y) of the electronic device 20, the first opening BV1, for example, has a width W1_BV1 on the first side SB1 in a direction parallel to the glass substrate SB (the direction x). The second opening BV2, for example, has a width W1_BV2 on the second side SB2 in a direction parallel to the glass substrate SB (the direction X). In this embodiment, the first opening BV1 extends to the inside of the glass substrate SB from the first side SB1 of the glass substrate SB, and has the inverted trapezoid shape. Therefore, the first opening BV1 may have a width W2_BV1 smaller than the width W1_BV1, in which the width W2_BV1 is the minimum width of the first opening BV1. In some embodiments, the width W2_BV1 of the first opening BV1 may correspond to a middle SB_C of the glass substrate SB. The middle SB_C of the glass substrate SB may, for example, have a range of ±10% extending from the center of the glass substrate SB in the top view direction (the direction Z) of the electronic device 20, but the disclosure is not limited thereto. In addition, in this embodiment, the second opening BV2 extends to the inside of the glass substrate SB from the second side SB2 of the glass substrate SB, and has the normal trapezoidal shape. Therefore, the second opening BV2 may have a width W2_BV2 smaller than the width W1_BV2, in which the width W2_BV2 is the minimum width of the second opening BV2. In some embodiments, the width W2_BV2 of the second opening BV2 may correspond to the middle SB_C of the glass substrate SB. In some embodiments, the junction of the side wall of the first opening BV1 and the side wall of the second opening BV2 may be discontinuous, and the first opening BV1 and the second opening BV2 are staggered to each other, but is not limited thereto. In other embodiments, the junction of the side wall of the first opening BV1 and the side wall of the second opening BV2 may be continuous, so that the through via TV2 has the smooth side wall.

In this embodiment, the glass substrate SB has the thickness T_SB greater than or equal to 50 μm and less than or equal to 2 mm in the top view direction (the direction Z) of the electronic device 20. For example, the thickness T_SB of the glass substrate SB may be 50 μm, 70 μm, 100 μm, 500 μm, 1 mm, 1.5 mm, 2 mm or any of the above numerical ranges, but the disclosure is not limited thereto.

The first circuit structure CS1 is, for example, disposed on the first side SB1 of the glass substrate SB. In this embodiment, the first circuit structure CS1 is part of the first connection structure 100. In detail, from another perspective, the first connection structure 100 includes the first metal structure MS1 disposed in the through via TV2 of the glass substrate SB and the first circuit structure CS1 disposed on the glass substrate SB (not disposed in the through via TV2). In this embodiment, the first circuit structure CS1 at least partially overlaps the through via TV2. Based on this, the first circuit structure CS1 may be electrically connected to the first metal structure MS1 located in the through via TV2, for example. The first circuit structure CS1 and the first metal structure MS1 may each include the seed layer SEED1 and the metal layer M1. For detailed description, please refer to the above embodiments, which is not repeated herein.

The second circuit structure CS2 is, for example, disposed on the second side SB2 of the glass substrate SB. In this embodiment, the second circuit structure CS2 is part of the second connection structure 200. In detail, from another perspective, the second connection structure 200 includes the second metal structure MS2 disposed in the through via TV2 of the glass substrate SB and the second circuit structure CS2 disposed on the glass substrate SB (not disposed in the through via TV2). In this embodiment, the second circuit structure CS2 at least partially overlaps the through via TV2. Based on this, the second circuit structure CS2 may be electrically connected to the second metal structure MS2 located in the through via TV2, for example. The second circuit structure CS2 and the second metal structure MS2 may each include the seed layer SEED2 and the metal layer M2. For detailed description, please refer to the above embodiments, which is not repeated herein.

In this embodiment, the first circuit structure CS1 and the second circuit structure CS2 are electrically connected to each other through the through via TV2, and the seed layer SEED1 of the first circuit structure CS1 id in contact with the second seed layer SEED2 of the second circuit structure CS2 to form an interface IN. Since the first opening BV1 and the second opening BV2 are staggered to each other, a width of the interface IN may be, for example, smaller than the width W2_BV1 of the first opening BV2 and the width W2_BV2 of the second opening BV2. In some embodiments, the interface IN may correspond to the middle SB_C of the glass substrate SB, but is not limited thereto.

FIG. 6 is a partial cross-sectional view of an electronic device according to the third embodiment of the disclosure. It should be noted that the embodiment of FIG. 6 can use the same reference numerals and parts as the embodiment of FIG. 3, where the same reference numerals indicate the same or similar components, and the description of the same technical content is omitted.

In this embodiment, an electronic device 30 includes the glass substrate SB, the first circuit structure CS1, and the second circuit structure CS2.

The glass substrate SB has, for example, the first side SB1 and the second side SB2 relative to the first side SB1, and includes a through via TV3. In this embodiment, the through via TV3 of the glass substrate SB is connected by the first opening BV1′ formed on the first side SB1 and the second opening BV2′ formed on the second side SB2. The junction between the side wall of the first opening BV1′ and the side wall of the second opening BV2′ is continuous and smooth, so that the through via TV3 has the smooth side wall, but the disclosure is not limited thereto. In the cross-sectional direction (the direction Y) of the electronic device 30, the through via TV3 may have a width W_TV3. The width W_TV3 is smaller than a width W1_BV1′ of the first opening BV1′ on the first side SB1 and smaller than a width W1_BV2′ of the second opening BV2′ on the second side SB2. In some embodiments, the width W_TV3 may correspond to the middle SB_C of the glass substrate SB, but is not limited thereto. For the introduction of the first opening BV1′, the second opening BV2′, the width W1_BV1′, the width W1_BV2′, and the middle SB_C, please refer to the first opening BV1, the second opening BV2, the width W1_BV1, the width W1_BV2, and the middle SB_C of the previous embodiments, which is not repeated herein.

In this embodiment, the glass substrate SB has the thickness T_SB greater than or equal to 50 μm and less than or equal to 2 mm in the top view direction (the direction Z) of the electronic device 30. For example, the thickness T_SB of the glass substrate SB may be 50 μm, 70 μm, 100 μm, 500 μm, 1 mm, 1.5 mm, 2 mm or any of the above numerical ranges, but the disclosure is not limited thereto.

The first circuit structure CS1 is, for example, disposed on the first side SB1 of the glass substrate SB. The second circuit structure CS2 is, for example, disposed on the second side SB2 of the glass substrate SB. For the detailed descriptions of the first circuit structure CS1 and the second circuit structure CS2, please refer to the above embodiments, which are not repeated herein.

In this embodiment, the first circuit structure CS1 and the second circuit structure CS2 are electrically connected to each other through the through via TV3. The seed layer SEED1 of the first circuit structure CS1 is in contact with the second seed layer SEED2 of the second circuit structure CS2 to form the interface IN. Since the first opening BV1′ and the second opening BV2′are not staggered to each other, the width W_TV3 may be, for example, the width of the interface IN and the minimum width of the through via TV3. In some embodiments, the interface IN may correspond to the middle SB_C of the glass substrate SB, but is not limited thereto.

In summary, in the manufacturing method of an electronic device provided by an embodiment of the disclosure, by forming the first opening in the form of the blind hole in the glass substrate, situations of contamination mechanisms and/or the glass substrate that is difficult to be absorbed can be reduced in the subsequent process of manufacturing the electronic device, which can reduce the time and cost of cleaning the machine and also reduce the situation where the glass substrate is not adsorbed and moves in the subsequent process. In summary, the manufacturing method of an electronic device provided by an embodiment of the disclosure can reduce the process cost of the manufactured electronic device and improve the yield of the manufactured electronic device. In addition, the through via penetrating the glass substrate may be formed by performing the thinning process or a process of forming the second opening on the other side of the glass substrate where the first opening is not formed.

Furthermore, in the manufacturing method of an electronic device provided by another embodiment of the disclosure, after forming the through via penetrating the glass substrate, through filling the hole plugging material into some of the through vias of the glass substrate first, situations of contamination mechanisms and/or the glass substrate that is difficult to be absorbed can be reduced in the subsequent process of manufacturing the electronic device, thereby reducing the time and cost of cleaning the machine, and also reducing the situation where the glass substrate is not adsorbed and moves in the subsequent process. In summary, the manufacturing method of an electronic device provided by another embodiment of the disclosure can also reduce the process cost of the manufactured electronic device, and can further improve the yield of the manufactured electronic device.

What is claimed is:

1. An electronic device, comprising:
a glass substrate, having a first side and a second side relative to the first side and comprising a through via;
a first circuit structure, disposed on the first side, wherein the first circuit structure at least partially overlaps the through via; and
a second circuit structure, disposed on the second side, wherein the second circuit structure at least partially overlaps the through via,
wherein the first circuit structure and the second circuit structure are electrically connected through the through via, and a thickness of the glass substrate is greater than or equal to 50 μm and less than or equal to 2 mm.

2. The electronic device according to claim 1, wherein the through via is connected by a first opening formed on the first side and a second opening formed on the second side, in a cross-sectional direction, the first opening has a first width on the first opening, the second opening has a second width on the second side, and the through via has a third width in a middle of the glass substrate, wherein the first width is greater than the third width, and the second width is greater than the third width.

3. The electronic device according to claim 2, further comprising:
a first metal structure, disposed in the first opening and electrically connected to the first circuit structure; and
a second metal structure, disposed in the second opening and electrically connected to the first metal structure and the second circuit structure,
wherein the first metal structure comprises a first seed layer, the second metal structure comprises a second seed layer, wherein in the through via, the first seed layer is in contact with the second seed layer to form an interface.

4. The electronic device according to claim 2, wherein the first opening is staggered with the second opening.

5. The electronic device according to claim 2, wherein the first opening is continuous with the second opening.

6. The electronic device according to claim 2, wherein the first width of the first opening shortens in a direction extending from the first side of the glass substrate toward a center of the glass substrate.

7. The electronic device according to claim 2, wherein the second width of the second opening is shortened in a direction extending from the second side of the glass substrate toward a center of the glass substrate.

8. The electronic device according to claim 1, further comprising:
a first metal structure, disposed in the through via and electrically connected to the first circuit structure and the second circuit structure,
wherein the first metal structure comprises a first seed layer, wherein the first seed layer is in contact with the second circuit structure in the through via.

9. The electronic device according to claim 8, wherein the first width of the through via shortens in a direction extending from the first side of the glass substrate toward the second side of the glass substrate.

10. The electronic device according to claim 8, further comprising:
a protective layer, disposed on a surface of the first circuit structure away from the glass substrate.

11. A method of manufacturing an electronic device, comprising:
providing a glass substrate, wherein the glass substrate has a first side and a second side relative to the first side;
forming a first opening on the first side;
forming a second opening on the second side;
forming a first circuit structure on the first side, wherein the first circuit structure at least partially overlaps the first opening; and
forming a second circuit structure on the second side, wherein the second circuit structure at least partially overlaps the second opening,
wherein the first opening and the second opening are connected to form a through via of the glass substrate, and the first circuit structure and the second circuit structure are electrically connected through the through via.

12. The method of manufacturing an electronic device according to claim 11, further comprising filling a hole plugging material into at least one of the first opening and the second opening.

13. The method of manufacturing an electronic device according to claim 12, further comprising removing the hole plugging material.

14. The manufacturing method of an electronic device according to claim 12, wherein forming the first circuit structure on the first side is performed after filling the hole plugging material into at least one of the first opening and the second opening.

15. The manufacturing method of an electronic device according to claim 11, further comprising:
filling a first metal structure in the first opening, and filling a second metal structure in the second opening, wherein the first metal structure is electrically connected to the first circuit structure, and the second metal structure is electrically connected to the first metal structure and the second circuit structure.

16. The method of manufacturing an electronic device according to claim 14, wherein filling the first metal structure in the first opening and filling the second metal structure in the second opening comprises:
forming a first seed layer on the first side of the glass substrate;
forming a first metal layer on the first seed layer;
forming a second seed layer on the second side of the glass substrate; and
forming a second metal layer on the second seed layer,
wherein in the through via, the first seed layer is in contact with the second seed layer contact to form an interface.

17. The manufacturing method of an electronic device according to claim 11, wherein after forming the first circuit structure on the first side, a protective layer is formed on a surface of the first circuit structure away from the glass substrate.

18. The method of manufacturing an electronic device according to claim 11, wherein the first opening is staggered with the second opening.

19. The method of manufacturing an electronic device according to claim 11, wherein the first opening is continuous with the second opening.

20. The manufacturing method of an electronic device according to claim 11, wherein the glass substrate has a thickness greater than or equal to 50 μm and less than or equal to 2 mm.
